(19) United States
(12) Patent Application Publication
(10) Pub. No.: US 2008/0236665 A1
(43) Pub. Date: Oct. 2, 2008

(54) Method for Rapid Liquid Phase Deposition of Crystalline Si Thin Films on Large Glass Substrates for Solar Cell Applications

(76) Inventors: Jianming FU, Palo Alto, CA (US); Zheng XU, Pleasanton, CA (US)

Correspondence Address: GLENN PATENT GROUP, 3475 EDISON WAY, SUITE L, MENLO PARK, CA, 94025, US

(21) Appl. No.: 11/695,495

(22) Filed: Apr. 2, 2007

(51) Int. Cl. H01L 31/00; B05C 11/00; B05D 5/12; C23C 14/54

(52) U.S. Cl. 136/261; 118/600; 118/712; 118/58; 427/74; 427/9

(57) ABSTRACT

A method for liquid phase deposition of crystalline silicon thin films, and a high efficiency solar cell that is fabricated using crystalline silicon thin film technology, has the performance of a crystal silicon solar cell, but at the cost level per unit area of a solar cell fabricated using an amorphous silicon thin film. The crystal thin film uses only 10% or less of the amount of silicon used in a wafer-based solar cell. Because of the maturity of silicon technology in semiconductor industry, this approach not only enables high volume, automated production of solar cells on a very large, low-cost substrate, but also increases the area throughput up to 10000 cm²/min from 942 cm²/min in case of CZ crystal growth.

### BACKGROUND OF THE INVENTION

1. Technical Field

The invention relates to liquid phase deposition of crystalline Si thin films and solar cells. More particularly, the invention relates to a high efficiency solar cell that is fabricated using crystalline silicon thin film technology.

2. Description of the Prior Art

Rising fuel costs and increasing worldwide energy demands have created a need for alternatives to conventional, e.g. hydrocarbon-based, sources of energy. Solar generated electricity is becoming a practical solution that addresses the increasing energy demand and may eventually replace the conventional hydrocarbon fueled power plant. Currently, solar electricity only accounts for 1.5% of the 5000 GW electricity market. The total available market for solar cells reached $4B in 2005 and is increasing rapidly, with a CAGR of 25-30% for the next ten years.

A simple solar cell consists of two layers of semiconductor material, typically silicon, sandwiched together between metal contacts. One layer, of n-type material, contains negatively charged free electrons; the other layer, of p-type material, contains positively charged “holes,” which are empty electron states in the valence band of semiconductors. At the junction where the two layers meet, electrons from the n-type region diffuse into the p-type region, and vice versa for holes the p-type region. The electrons that diffuse from n-type region leave behind positive charge centers, and holes from p-type regions leave behind negative charge centers. These charges establish an electric field preventing further diffusion of electrons and holes, until equilibrium is reached. When light of an appropriate wavelength strikes the solar cell, the individual packets of energy, called photons, excite the electrons to the conduction band, leaving a hole in valence band, simultaneously creating an electron-hole pairs. The electric field then coaxes these free electrons and holes to move in opposite directions. The result is a build-up of free electrons in the n-type material, and a build up of holes, i.e. a shortage of electrons, in the p-type material. An external circuit provides a path for the electrons to return to the p-type material, producing an electric current along the way that continues as long as light strikes the solar cell.

Solar cells in accordance with the prior art are presently produced by either of two known methods:

For the first generation, the solar cells were formed on poly or single crystal silicon wafers that are 150 um-250 um thick. For each MW electricity output, 14.78 tons of silicon is needed because of losses that result from the manufacturing process. The recent supply shortage and price hiking of silicon feedstock also creates a hurdle to the growth of the solar cell industry. Efforts have been made to increase the utilization, such as with string ribbon and EFG, but the films are still rather thick.

For the second generation, the solar cells are formed using thin films on substrates. Compound semiconductors, such as CdTe and CIGS thin films, have been investigated as alternative to silicon and demonstrate reasonable conversion efficiency. However, the technology maturity, the toxicity of the materials used to manufacture such cells, and the limited availability of materials used to manufacture such cells, such as indium, tellurium, and selenium, are casting a shadow on the future of these types of solar cell.

Amorphous silicon thin film is also used to manufacture solar cells on substrates. However, the energy conversion efficiency of such cells is low (˜5-8%) due to low carrier mobility in amorphous silicon and the thin film thickness. The film has to be thin for photon generated carriers to reach the collecting electrodes due to low carrier lifetime and mobility. The thin a-silicon film cannot absorb the solar energy effectively due to low absorption coefficient and band gap mismatch with solar spectrum. Usually this type of cell has a high open-circuit voltage (Voc), but a low short-circuit current (Jsc) and filling factor (FF). The energy conversion efficiency of such cell also degrades as the level of hydrogen within the film decreases.

It is thought that 50-100 um thick silicon films are the best for high efficiency solar cell manufacturing. However, it is difficult to handle this material in the form of stand-alone wafers. On the other hand, there is no effective method for producing 50-100 um thin film solar cells at a production-worthy rate.

Noboru Tsuya has described a method for growing thin silicon ribbons in U.S. Pat. No. 4,682,206. In the '206 patent, the molten silicon is ejected through thin nozzles onto a surface having a temperature that is below 400° C., thus forming a flexible silicon ribbon that is separated from the substrate. The cooling rate is super fast to obtain small grains of between 5 um and 200 um for flexibility. Phillippe Knauth et al describe a sheet drawing process from melt in U.S. Pat. No. 5,298,109. A melt of silicon is crystallized on a moving substrate. However, the films formed in this method are rather thick, on the order of 0.5 mm.

In the prior art, solar cells are mounted onto solar glass by SOLAR EVA® which is the trade name of ethylene-vinyl acetate (EVA) encapsulating materials for solar modules made by Hi-Sheet Industries, Ltd. This step is typically followed by an inter-cell connection (see, for example, W. Mulligan, D. Rose, M. Cudzinovic, D. DeCeuster, K. McIntosh, D. Smith, R. Swanson, Manufacturing of Solar Cells with 21% Efficiency, SunPower Corporation). Thus, interconnection of the cells is accomplished by additional steps, including the provision of solder pads and soldering of ribbons to the pads, sometimes with bending from the backside to the front side of the substrate. This increases cost and also may result in reliability problems due to thermal mismatches.

It would be advantageous to provide an improved solar cell that overcame the above noted limitations of the prior art.

### SUMMARY OF THE INVENTION

The presently preferred embodiment of the invention comprises a method for liquid phase deposition of crystalline Si thin films onto glasses, and the fabrication of high efficiency solar cells using crystalline silicon thin film technology. This deposition method enables rapid deposition of crystalline Si thin films on very large glass substrates with a deposition rate of up to 50 micron per minute. A solar cell that is fabricated on this crystalline Si thin film, as disclosed herein, that equal energy conversion efficiency to that of a cell that is made of a crystal Si wafer, but uses only 10% of the amount of silicon used by a wafer-based solar cell, considering the losses prior to reaching the final usable wafer thickness of ˜200 μm. Therefore, the solar cell based on this invention has the performance of a crystal silicon solar cell, but at a cost per unit area similar to that of a solar cell fabricated using an amorphous silicon thin film. Because of the maturity of silicon technology in semiconductor industry, this approach not only enables high volume, automatic production of solar cells on a very large, low-cost substrate, but also increases the area throughput up to 10000 cm²/min from 942 cm²/min in case of CZ crystal growth. With this approach, the manufacturing cost becomes much less sensitive to silicon price fluctuations, and the solar module cost is expected to be reduced to around $1/Wp due to silicon material saving and factory output improvement. This is expected to provide a solar module that propels solar electricity penetration in the energy market.

Rapid Liquid Phase Deposition of Crystalline Si Thin Films on Large Glass Substrates

In this embodiment of the invention, a 25-200 μm, but preferably 50-100 μm silicon film is deposited on a glass substrate. The silicon is first melted in a container, then dispensed through nozzles onto a moving heated substrate. The substrate is maintained at an elevated temperature for a specified time to reduce defects within the film. Dispensing of silicon onto the substrate is accomplished by controlling the capillary force, the pressure difference inside and outside of the container in which the silicon is melted, and the wetting property of the nozzle and the substrate. In one embodiment, the substrate is moved linearly at a rate of 1 cm/s or higher. The deposition thickness is controlled by factors that include the rate at which silicon is dispensed, the substrate wettability, the substrate moving rate, and substrate temperature. The glass substrates are chosen for its low cost, similar expansion coefficient to silicon, and high light transmission.

Photovoltaic Device on Crystalline Silicon Thin Film

Solar cell, efficiency between 12% and 18% can be achieved with devices that are manufactured on the crystalline silicon thin films described above. In this embodiment, the glass is first deposited with an antireflection coating, such as hydrogenated SiNx, followed by an optional hydrogenated SiO2 passivation layer, and then by a layer of hydrogenated. amorphous silicon. At a next step, a layer of 50-100 um crystalline silicon with grains >30 um is formed on the substrate. This layer is used as the absorber for the solar cell. An p+/n+ interdigitated back contact (IBC) is formed in the back of the device for collection of electron-hole pairs generated in the entire crystalline silicon layer.

### BRIEF DESCRIPTION OF THE DRAWINGS

FIG. 1 is a schematic diagram showing crystalline thin film deposition in connection with the fabrication of a solar cell according to the invention;

FIGS. 2a and 2b are the schematic diagrams showing initiation of deposition (FIG. 2a) and capillary action (FIG. 2b) during thin film deposition according to the invention;

FIG. 3 is a schematic diagram showing a coating on a sloped area to stop further wetting of Si beyond the face according to the invention;

FIGS. 4a, 4b, and 4c are diagrams that provide a top schematic view (FIG. 4a), sectioned schematic view (FIG. 4b), and side view (FIG. 4c) showing melted silicon being dispensed through multiple nozzles onto a moving substrate according to the invention;

FIGS. 5a and 5b provide side view (FIG. 5a) and top view (FIG. 5b) schematic diagrams showing Si granules and a distribution tube for deposition of melted silicon onto large substrates according to the invention; and

FIG. 6 is a schematic diagram showing a photovoltaic device formed on a crystalline silicon thin film according to the invention.

### DETAILED DESCRIPTION OF THE INVENTION

The presently preferred embodiment of the invention comprises a method for liquid phase deposition of crystalline Si thin films onto glass. A solar cell that is fabricated using the invention disclosed herein has the performance of a crystal silicon solar cell, but at per unit area cost that is similar to that of a solar cell that is fabricated using an amorphous silicon thin film. In the fabrication of a conventional crystal Si solar cell, although the wafer thickness used is slightly below 200 μm, there are significant losses from raw material to the wafers, such as growth, cutting, and polishing. In the invention, the crystal thin film uses only 10% of the amount of silicon used by a wafer-based solar cell per unit area. The cell manufacturing process follows existing Si processing techniques. Because of the maturity of silicon technology in semiconductor industry, this approach not only enables high volume, automated production of solar cells on a very large, low-cost substrate, but also increases the area throughput up to 10000 cm²/min from 942 cm²/min in case of CZ crystal growth. With this approach, the manufacturing cost becomes much less sensitive to silicon price fluctuations, and the product cost is expected to be reduced to around $1/Wp due to silicon material saving and factory output improvement. This is expected to provide a solar cell that propels solar electricity penetration in the energy market.

Rapid Liquid Phase Deposition of Crystalline Si Thin Films on Large Glass Substrates

In the invention herein disclosed, a 50-100 um silicon film is produced on a glass substrate. The silicon is first melted in a container or crucible, and then dispensed through nozzles onto a moving heated glass substrate. The substrate is maintained at a high temperature, such as >530° C. of glass transformation point, before and during the deposition. The substrate is cooled down slowly to 300° C. to reduce defects within the film. BoroFloat glasses can be used for the substrate for its similar thermal expansion coefficient to silicon. Dispensing of melted silicon is performed by using capillary force, controlling the pressure difference inside and outside of the container, and controlling the wetting property of the substrate. In general, the pressure difference is less than 10 Torr, depending on surface tension and the deposition rate desired. The substrate can be moved linearly at a rate of 1 cm/s or higher. The deposition thickness is controlled by factors that include the rate at which silicon is dispensed, the substrate moving rate, and substrate temperature. For example, the dispensing rate is 2.5×10⁻² cm³/s per 1 cm of nozzle length for a 50 μm film grown at a substrate moving rate of 5 cm/s. For a nozzle that is 0.5 mm wide, the velocity of flow is 0.5 cm/s, in the laminar flow regime. The substrate temperature should be higher than 530C. The substrate temperature, the viscosity of the Si melt, and the substrate wettability determine the smoothness of the film.

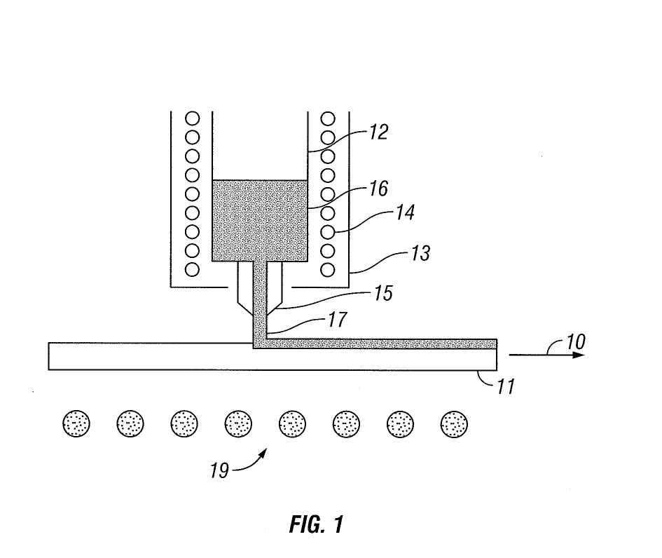

FIG. 1 is a schematic diagram showing crystalline thin film growth in connection with the fabrication of a solar cell according to the invention. In FIG. 1, a container, e.g. a crucible 12, incorporates a heater 14 that heats and melts silicon 16 within the crucible. The crucible is preferably made of high.purity graphite. The crucible also incorporates a heat shield 13 and one or more nozzles 15. A flow of melted silicon 17 is dispensed from the nozzles onto a substrate 11 that is heated by heat lamps 19. The substrate is moved past the nozzle, as indicated by the arrow 10. Those skilled in the art will appreciate that the nozzles may be moved instead of the substrate as long as there is relative motion between the nozzles and the substrate during deposition of the melted silicon onto the substrate. The crucible and heating mechanism used to melt the silicon in the crucible can be any such devices as are well known in the semiconductor industry. Likewise, the substrate may be heated using a mechanism other than a heat lamp.

In accordance with the invention, a thin silicon film of 50-100 um is formed on a large substrate, e.g. 1 m². The thin film of silicon is used as a base for the formation of photovoltaic devices. Deposition of a thin silicon film onto a substrate of such size can be completed in about one minute. The film stays on the substrate for the subsequent photovoltaic device manufacturing. A preferred material for the substrate is BoroFloat glass, which has a similar expansion coefficient to that of silicon. This minimizes the chance of the silicon cracking on large substrates. Those skilled in the art will appreciate that other materials may be used for the substrate.

The substrate is heated and maintained at a high temperature, e.g. >530° C., which is a typical glass transformation temperature, during and shortly after deposition of the melted silicon onto the substrate to slow down cooling of the substrate, thus obtaining a film having a large grain size, e.g. >30 μm.

The process is carried out a chamber containing both the substrate and the Si liquid source. The chamber is purged by H₂ and Ar, with H₂>50%. The use of H₂ prevents the silicon surface from oxidation and passivates the grain boundaries, further enhancing the mobility of electrons and holes in a completed photovoltaic device. The liquid Si container is separately pumped and fed with a similar Ar:H₂ mixture. Thus, the pressure inside and outside of the liquid Si container, i.e. the chamber, is independently controlled.

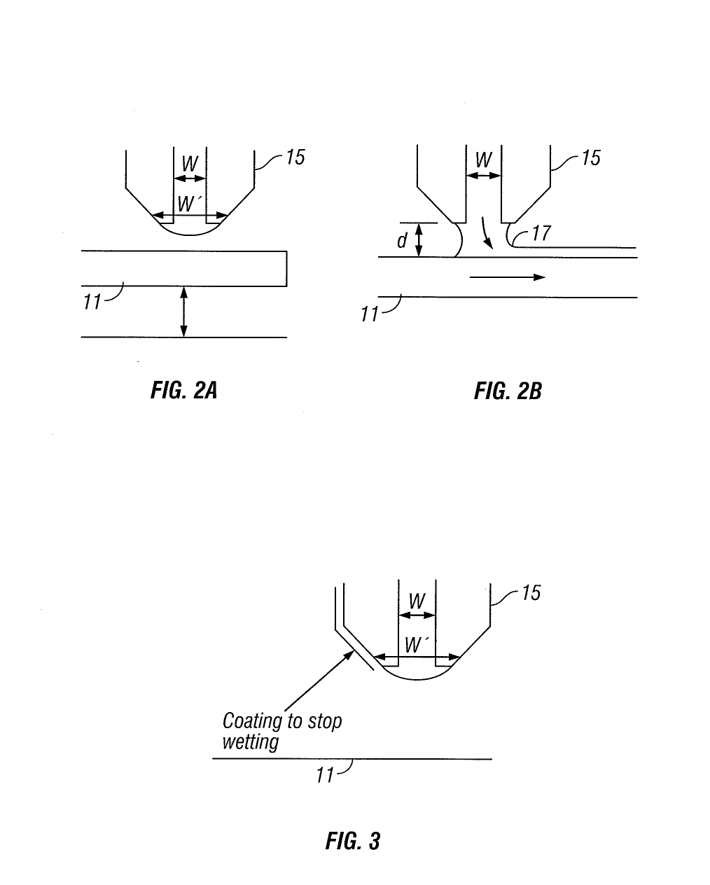

FIGS. 2a and 2b are schematic diagrams which illustrate the use of capillary action during silicon deposition. As silicon melted in the container, the liquid silicon is drawn into channels connecting to nozzles. Graphite is used as the crucible material due to good wetting of silicon on this material, thus enhancing the capillary action. The silicon continues to move down along the channel. until it reaches the openings as in FIG. 2a. It forms a curved surface, as shown in FIG. 2a. The curvature depends upon the wetting angle, surface tension of liquid silicon, the pressure difference between inside and outside of the container, and the height of the liquid. The deposition is initiated by bringing the moving substrate into contact with the liquid silicon. The substrate vertical position can be rapidly adjusted to the final deposition position right after the contact initiation. The subsequent deposition is conducted with the capillary action. The liquid silicon is continuously supplied through capillary motion onto the substrate. This provides more uniform deposition with thinner thickness. The distance d between the nozzle and the substrate depends upon the surface tension of liquid silicon and the width of nozzle w as well as the face width w′. The face width w′ will not be greater than 2 w. The ratio of d to w′ should not be more than 2:1.

The face width w′ is also controlled by stopping the further wetting of silicon to the sloped region. As shown in FIG. 3, this can be achieved by coating the sloped region with a thin layer of silicon dioxide, on which silicon tends to have large wetting angle. Other material can also be used to change the surface such that the silicon has poor wetting.

The substrate can be pre-coated with silicon to alter the surface wettability and adhesion, or as part of device structure. The substrate is preferably moved at a rate of >1 cm/s. The molten silicon is maintained at a temperature at which the viscosity and surface tension of silicon is in a suitable range to ensure the spreading of the silicon without forming bumps upon the moving substrate. This range is within 200 C above the Si melting point. The temperature of liquid Si is used to control the thickness of film.

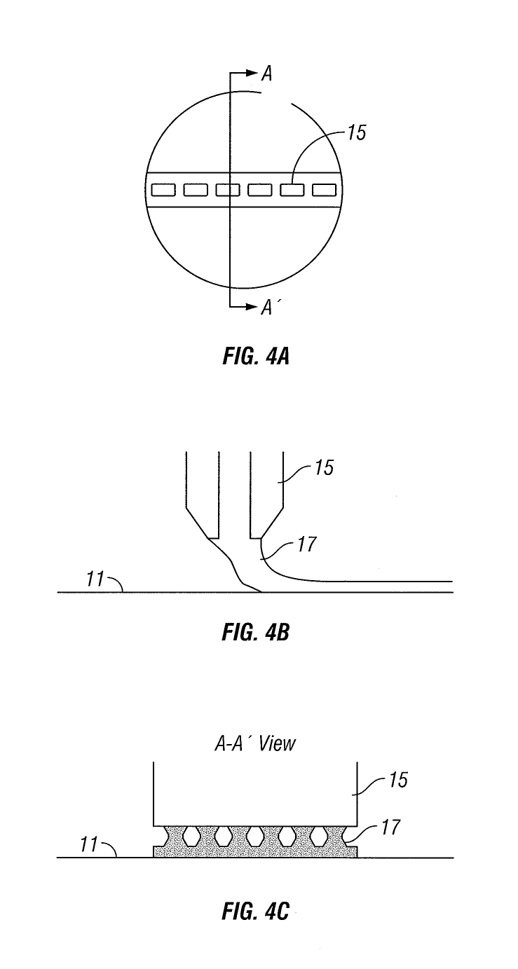

Multiple round or elongated dispensing holes can be arranged laterally to form thin films on large substrates. See FIGS. 4a, 4b, and 4c, which are diagrams that provide a top schematic view (FIG. 4a), sectioned schematic view (FIG. 4b), and side view (FIG. 4c) showing melted silicon 17 being dispensed through multiple nozzles 15 onto a moving substrate 11 according to the invention. The nozzle size is on the order of 0.025 mm-0.5 mm width and of various lengths between 0.5 and 20 mm. The aspect ratio of length-to-width is preferably below 5:1, i.e. for 0.5 mm of width, the length is less than 2.5 mm. Otherwise, the silicon tends to form balls due to surface tension and drips during the initiation of the deposition. The melted silicon from the parallel holes is spread on the surface due to wetting and low viscosity.

The distance between the holes is adjusted as appropriate for the uniformity of the film. For example, in the case that the separation of the holes are 0.5 mm, and the distance to the substrate is 1 mm, if the deposition right between the two neighboring holes is less than the deposition right under the holes, the separation needs to be reduced.

The preferred material for the crucible, i.e. container, and dispensing nozzle is high-purity graphite, with a thermal expansion coefficient similar to that of silicon. An alternative material comprises, for example, fused silica or boron nitride, lined with SiNx. The silicon in the reservoir of the container can be heated by any of a resistive heater, by inductive heating or arcing, or by other methods as are known in the art.

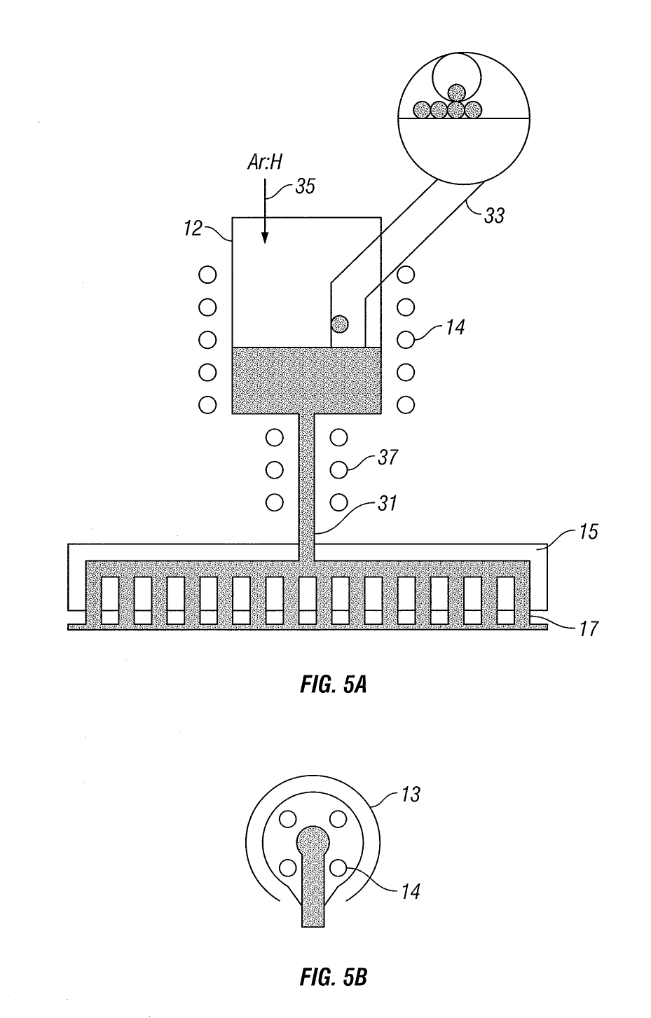

FIGS. 5a and 5b provide side view (FIG. 5a) and top view (FIG. 5b) schematic diagrams showing seeding of silicon granules and a distribution tube for deposition of melted silicon onto large substrates according to the invention. For scaling up, as shown in FIG. 5, a reservoir having a heat shield 13, e.g. the container or crucible 12 having a source of heat, such as a heating element 14, is connected to a tube 31 that is heated by a heating element 37. Similar multiple nozzles are formed at the bottom of the tube for silicon deposition. The reservoir is fed with silicon granules materials from a hopper 33 in a way which allows the reservoir to be evacuated and purged independently from the chamber containing the substrate.

In the presently embodiment of the invention, solar cells having an efficiency of between 12% and 18% can be manufactured on crystalline silicon thin films in methods known to the art.

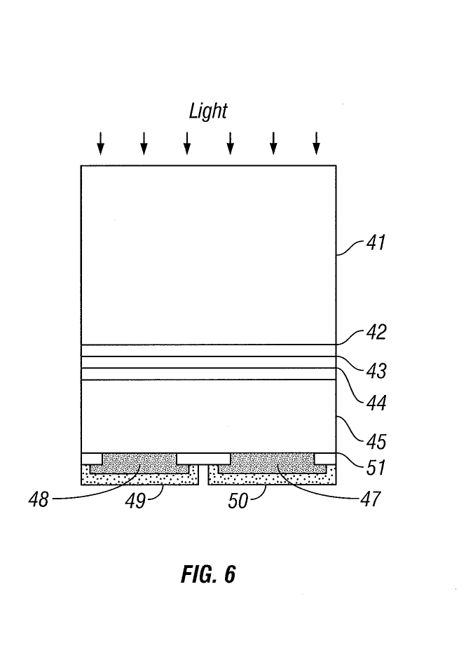

FIG. 6 is a schematic diagram showing an example of photovoltaic device 40 that is formed on a crystalline silicon thin film according to the invention. The glass substrate 41, preferably having a surface roughness of 0.1 micron, is first deposited with an antireflection coating 42, such as SiNx, followed by an optional SiO2 passivation layer 43, and then by a wetting layer of hydrogenated amorphous silicon 44. Then the photovoltaic device structure is manufactured on a crystalline Si thin film base 45 using conventional technical steps, including junction formation and metal contacts. The p+ and n+ region is formed on the back side. These p+ (47) and n+ (48) area are in interdigitated form, and are separated by the oxide layer Si left after the first etch. Interdigitated contacts comprising separated metal layers for n (49) and p (50) are formed in the back of the substrate for collection of electron-hole pairs generated in the entire crystalline silicon layer. These metal layers can be aluminum, which is also a good reflection material to reflect the unabsorbed light back into the base for further absorption. The entire manufacturing process can be conducted at a temperature below the glass transformation temperature, so that it is compatible with the low-cost substrates. Those skilled in the art will appreciate that the manner in which the foregoing layers are formed is a matter of choice, and that the various layers and structures that are used to form solar cells in accordance with the invention may be varied from the example provided above.

In accordance with the invention, a solar cell efficiency of between 12% and 18% is achieved using crystalline silicon thin films on glass substrates. This is a radical departure from the conventional method of first manufacturing solar cells on silicon wafers, and then mounting the cells onto glass, with an interconnect between the cells used to form the modules. The invention lowers the manufacturing cost, but achieves similar light energy conversion efficiency. In comparison with the use of amorphous silicon or microcrystal silicon thin film solar cells formed on glass substrates, devices made in accordance with the invention achieve higher efficiency because the large grain polycrystalline silicon provides higher carrier lifetime and mobility, and light absorption is much more pronounced using a thin film with the thickness around 50 um. The invention enables the automated manufacturing of solar cells on large substrates. The economy of scale lowers the cost of manufacturing.

Although the invention is described herein with reference to the preferred embodiment, one skilled in the art will readily appreciate that other applications may be substituted for those set forth herein without departing from the spirit and scope of the present invention. Accordingly, the invention should only be limited by the Claims included below.

1. A method for fabricating photovoltaic devices, comprising the steps of:
providing a substrate; and
forming a polycrystalline silicon film having a thickness of 25-200 μm and preferably, 50-100 um on said substrate;
wherein said silicon film comprises a base for the formation of photovoltaic devices.

2. The method of claim 1, further comprising the steps of:
melting silicon in a container or crucible;
heating said substrate;
establishing relative linear motion between said substrate and a plurality of nozzles associated with said container or crucible; and
dispensing said melted silicon through said plurality of nozzles onto said moving, heated substrate through a capillary motion.

3. The method of claim 1, further comprising the step of:
maintaining said substrate at a high temperature for a predetermined time to reduce defects within the film.

4. The method of claim 1, further comprising the step of:
dispensing of melted silicon by controlling a pressure difference inside and outside of said container or crucible.

5. The method of claim 1, further comprising the step of:
moving said substrate linearly at a rate of 1 cm/s or higher.

6. The method of claim 1 further comprising the step of:
controlling deposition thickness by factors that comprise any of a rate of dispensing, substrate wettability, a substrate moving rate, and substrate temperature.

7. The method of claim 1, said step of providing a substrate further comprising the step of:
providing a substrate of 1 m² or larger.

8. The method of claim 1, said step of providing a substrate further comprising the step of:
providing a transparent substrate.

9. The method of claim 1, said step of providing a substrate further comprising the step of:
providing a substrate made of glass.

10. The method of claim 1, said step of providing a substrate further comprising the step of:
providing a substrate made of a material which has a similar expansion coefficient to that of silicon.

11. The method of claim 2, said step of heating further comprising the step of:
maintaining said substrate at a high temperature that is >530° C. during and shortly after deposition of melted silicon onto said substrate to obtain a film having a large grain size that is >30 um.

12. The method of claim 1, further comprising the step of:
forming said silicon film either under vacuum or with an inert gas comprising either Ar or a mixture of H₂ and Ar.

13. The method of claim 1, further comprising the step of:
pre-coating said substrate with silicon to ensure good wettability, adhesion, and front face field to mitigate carrier loss for passivation.

14. An apparatus for providing a base for fabricating photovoltaic devices on a substrate, comprising:
means for melting silicon in a container or crucible;
means for heating said substrate; and
means for establishing relative linear motion between said substrate and a plurality of nozzles associated with said container or crucible; and
means for dispensing said melted silicon through said plurality of nozzles onto said moving, heated substrate;
wherein by a silicon film having a thickness of 50-100 um is formed on said substrate, said silicon film comprising a base for the formation of said photovoltaic devices.

15. The apparatus of claim 14, said plurality of nozzles further comprising:
multiple round or elongated dispensing holes that are arranged laterally to form thin silicon films on said substrates.

16. The apparatus of claim 14, said plurality of nozzles having a size of 0.025 mm-0.5 mm width, a selected length, and an aspect ratio preferably below 5:1.

17. The apparatus of claim 14, said means for dispensing further comprising:
means for controlling a pressure difference between a pressure inside and a pressure outside of said container.

18. The apparatus of claim 14, said container or crucible further comprising:
a conduit for conducting molten silicon to said plurality of nozzles.

19. A photovoltaic device fabricated in accordance with the method of any of claims 1 to 13.

20. A photovoltaic device fabricated with the apparatus of any of claim 14 to 18.
